(19) United States
(12) Patent Application Publication
(10) Pub. No.: US 2016/0042111 A1
(43) Pub. Date: Feb. 11, 2016

(54) LAYOUT METHOD OF SEMICONDUCTOR DEVICE AND METHOD OF FORMING SEMICONDUCTOR DEVICE

(71) Applicant: JI-YOON CHANG, PYEONGTAEK-SI (KR)

(72) Inventor: JI-YOON CHANG, PYEONGTAEK-SI (KR)

(21) Appl. No.: 14/716,604

(22) Filed: May 19, 2015

(30) Foreign Application Priority Data
Aug. 5, 2014 (KR) 10-2014-0100577

(51) Int. Cl. G06F 17/50; H01L 21/311; H01L 23/528; H01L 21/768

(52) U.S. Cl. CPC G06F 17/5077; G06F 17/5072; H01L 21/76802; H01L 21/76877; H01L 21/31144; H01L 23/528

(57) ABSTRACT

A layout method for use in fabricating a semiconductor device includes creating a contact layout including cell contact layouts and peripheral contact layouts using a computer, and creating an interconnection layout including cell interconnection layouts and peripheral interconnection layouts using the computer. The interconnection layout includes a plurality of line layouts and bride layouts. The line layouts include cell interconnection layouts and peripheral line layouts. The peripheral line layouts include a first peripheral line layout and a second peripheral line layout adjacent to each other, and the peripheral contact layouts include a misaligned contact layout interposed between the first and second peripheral line layouts. The bridge layout connects the first and second peripheral line layouts and overlaps the misaligned contact layout. In the method, the second peripheral line layout is divided along its length.

### PRIORITY STATEMENT

This application claims priority under 35 U.S.C. §119 to Korean Patent Application No. 10-2014-0100577 filed on Aug. 5, 2014, the disclosure of which is hereby incorporated by reference in its entirety.

### BACKGROUND

1. Technical Field

Embodiments of the inventive concept relate to a layout method of a semiconductor device and to a method of manufacturing the semiconductor device using the same.

2. Description of Related Art

As semiconductor devices become more highly integrated, the widths of interconnections and distances therebetween are being reduced leading to increasing complications. Thus, the random locations available for contacts of the devices are gradually becoming reduced. That is, it is becoming increasingly difficult to layout and then fabricate contacts and interconnections electrically connected to the contacts when manufacturing semiconductor devices according to design rules in demand.

### SUMMARY

In accordance with an aspect of the inventive concept, there is provided layout method of a semiconductor device, which includes creating a contact layout including cell contact layouts and peripheral contact layouts using a computer, each of contact layouts having a form corresponding to that of a contact of the semiconductor device, and creating an interconnection layout including a layout of cell interconnections and peripheral interconnections using the computer, and in which the creating of the interconnection layout comprises: creating a plurality of line layouts and a bridge layout, and a cutting step. The line layouts are spaced apart from each other by uniform distances in a first direction, have the same widths, and each has a linear form extending longitudinally in a second direction perpendicular to the first direction. The plurality of line layouts include cell interconnection layouts and peripheral line layouts, the peripheral line layouts including a first peripheral line layout and a second peripheral line layout adjacent to each other. Te peripheral contact layouts include a misaligned contact layout disposed between the first and second peripheral line layouts, and the bridge layout extends to and from the first and second peripheral line layouts in the first direction and overlapping the misaligned contact layout. The cutting step comprises cutting the second peripheral line layout into discrete parts separated from each other in the second direction.

In accordance with another aspect of the inventive concept, there is provided a method of forming a semiconductor device, which includes forming a contact mask and an interconnection mask using the layout method summarized above, forming an interlayer insulating layer on a substrate having a memory cell array area and a peripheral circuit area, forming cell contact patterns and peripheral contact patterns passing through the interlayer insulating layer using the contact mask; and forming cell interconnections and peripheral interconnections on the interlayer insulating layer using the interconnection mask.

In accordance with another aspect of the inventive concept, there is provided a method of manufacturing a semiconductor device, which includes a computer-aided design process of creating a layout of mask openings corresponding to contacts of the device and interconnections of the device, and a fabrication operation including a semiconductor process, based on the design process, of forming the contacts and interconnections on a substrate both in a memory cell area of the device and a peripheral circuit area of the device outside the memory cell area. The computer-aided design process comprises: creating a contact layout including contact layout sections defining the contours and relative locations of cell contacts to be formed by the fabrication operation in the memory cell area, and peripheral contact layout sections defining the contours and relative locations of peripheral contacts to be formed in the peripheral circuit area by the fabrication operation, and creating an interconnection layout defining the contours and relative locations of cell interconnections to be formed by the fabrication operation in the memory cell area and peripheral interconnections to be formed by the fabrication operation in the peripheral circuit area. The interconnection layout includes line-shaped layout sections and a bridge layout section. The line-shaped layout sections are of equal widths, are spaced apart from each other by uniform distances in a first direction, and each of the line-shaped layout sections extends longitudinally in a second direction perpendicular to the first direction. Also, the line-shaped layout sections include a first peripheral line-shaped layout section and a second peripheral line-shaped layout section adjacent to each other, and the peripheral contact layout sections include a misaligned contact layout section interposed between the first and second peripheral line layout sections with the contact layout and the interconnection layout being superimposed. The bridge layout section interconnects the first and second peripheral line layout sections in the first direction, and overlaps the misaligned contact layout section with the contact layout and the interconnection layout being superimposed. The second peripheral line layout section is discontinuous in the second direction so as to have discrete parts separated from each other in the second direction, only one of the discrete parts being connected to the bridge layout section. The semiconductor process comprises forming an interlayer insulating layer on the substrate as extending over both the memory cell array area and peripheral circuit area, forming contacts that pass through the interlayer insulating layer, and forming conductive interconnection patterns on the interlayer insulating layer as electrically conductively connected to the contacts.

### BRIEF DESCRIPTION OF THE DRAWINGS

The foregoing and other features and advantages of the inventive concepts will be more apparent from the detailed description of preferred embodiments of the inventive concepts, as illustrated in the accompanying drawings in which like reference characters designate like parts throughout the different views. The drawings are not necessarily to scale, emphasis instead being placed upon illustrating the principles of the inventive concepts. In the drawings:

FIG. 1 is a block diagram of a semiconductor device that may be fabricated in accordance with the inventive concept;

FIGS. 2A and 2B are flowcharts showing an embodiment of a method of fabricating a semiconductor device in accordance with the inventive concept, including a method of creating a layout and the fabricating elements of the device using the layout;

FIG. 3 is a layout diagram of a contact layout created in accordance with the inventive concept;

FIGS. 4A, 4B, 4C and 4D are layout diagrams illustrating an example of the creating of an interconnection layout of a semiconductor device layout in accordance with the inventive concept;

FIGS. 5A and 5B are layout diagrams for use in illustrating another example of the creating of an interconnection layout of a semiconductor device in accordance with the inventive concept;

FIGS. 6, 7, 8 and 9 are cross-sectional views of a semiconductor device, during the course of its manufacture, in accordance with the inventive concept;

FIG. 10 is a one example of a layout of contact patterns and interconnections of a semiconductor device made in accordance with the inventive concept;

FIG. 11 is another example of a layout of contact patterns and interconnections of a semiconductor device made in accordance with the inventive concept;

FIG. 12 is a schematic plan view of a semiconductor module in accordance with the inventive concept;

FIG. 13 is a conceptual block diagram of an electronic system in accordance with the inventive concept; and

FIG. 14 is a conceptual block diagram of another electronic system in accordance with the inventive concept.

### DETAILED DESCRIPTION OF THE EMBODIMENTS

Various embodiments will now be described more fully with reference to the accompanying drawings in which some embodiments are shown. These inventive concepts may, however, be embodied in different forms and should not be construed as limited to the embodiments set forth herein. Rather, these embodiments are provided so that this disclosure is thorough and complete and fully conveys the inventive concept to those skilled in the art. In the drawings, the sizes and relative sizes of layers and regions may be exaggerated for clarity. Like numerals refer to like elements throughout.

The exemplary embodiments of the invention will be described with reference to cross-sectional views, plan views, and block diagrams, which are ideal exemplary views. Forms of the embodiments may be modified by the manufacturing technology and/or tolerance. Therefore, the embodiments of the invention are not intended to be limited to illustrated specific forms, and include modifications of forms generated according to the manufacturing processes. Therefore, areas illustrated in the drawings have overview properties, shapes of the areas are illustrated special forms of the areas of a device, and are not intended to limit the scope of the invention.

In the drawings, the lengths and thicknesses of layers and regions may be exaggerated for clarity. In addition, it will be understood that when a first element is referred to as being “on” a second element, the first element may be directly on the second element, or a third element may be interposed between the first element and the second element. Like numerals refer to like elements throughout the specification.

Spatially relative terms, such as “upper end,” “lower end,” “upper surface,” “lower surface,” “upper part,” “lower part,” and the like, may be used herein for ease of description to distinguish relative locations of elements. For example, when an upper part is used as a top in the drawing and a lower part is used as a bottom in the drawing for convenience, the upper part could be termed the lower part and the lower part could be termed the upper part without departing from the scope of the present invention.

Furthermore, although terms, such as “upper,” “intermediate,” “lower,” and the like, may be used herein for ease of description to distinguish relative locations of elements, the present inventive concept should not be limited by these terms. Therefore, the terms, such as “upper,” “intermediate,” “lower,” and the like, may also be used to describe the elements in the specification by being replaced by terms, such as “first,” “second,” “third,” and the like.

It will be understood that, although the terms “first,” “second,” etc. may be used herein to describe various elements, these elements should not be limited by these terms. These terms are only used to distinguish one element from another. For example, a first element could be termed a second element, and similarly, a second element could be termed a first element, without departing from the scope of the inventive concept.

The terminology used herein is for the purpose of describing particular embodiments only and is not intended to be limiting of the present inventive concept.

Elements of the invention referred to in singular may number one or more, unless the context clearly indicates otherwise. It will be Furthermore understood that the terms “comprises,” “comprising,” “includes,” and/or “including,” when used herein, specify the presence of stated features, numbers, steps, operations, elements, components, and/or groups thereof, but do not preclude the presence or addition of one or more other features, numbers, steps, operations, elements, components, and/or groups thereof.

Unless otherwise defined, all terms (including technical and scientific terms) used herein are to be interpreted as is customary in the art to which this invention belongs. It will be Furthermore understood that terms in common usage should also be interpreted as is customary in the relevant art and not in an idealized or overly formal sense unless expressly so defined herein.

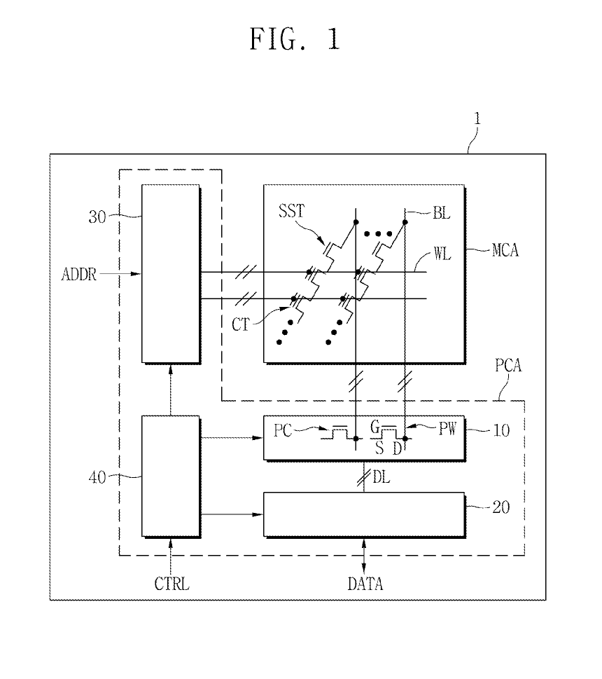

FIG. 1 is a block diagram showing an embodiment of a semiconductor device in accordance with the inventive concept.

Referring to FIG. 1, semiconductor device 1 may include a memory cell array area MCA and a peripheral circuit area PCA disposed around the memory cell array area MCA.

The memory cell array area MCA may include cell transistors CT, select transistors SST connected to the cell transistors CT, bit lines BL connected to the select transistors SST, and word lines WL connected to the cell transistors CT.

The peripheral circuit area PCA may include a read/write circuit area 10, a data input/output circuit area 20, an address decoder circuit area 30, and a control logic circuit area 40.

The memory cell array area MCA may be connected to the address decoder circuit area 30 through the word lines WL, and the read/write circuit area 10 through the bit lines BL.

The address decoder circuit area 30 may operate in response to a control of the control logic circuit area 40.

The address decoder circuit area 30 may receive an address ADDR from the outside. The address decoder circuit area 30 may decode a row address of the received address ADDR, and select a corresponding word line of the plurality of word lines WL. Furthermore, the address decoder circuit area 30 may decode a column address of the received address ADDR, and transfer the decoded column address to the read/write circuit area 10. For example, the address decoder circuit area 30 may include a row decoder, a column decoder, an address buffer, etc.

The read/write circuit area 10 may be connected to the memory cell array area MCA through the bit lines BL, and to the data input/output circuit area 20 through the data lines DL. The read/write circuit area 10 may operate in response to the control of the control logic circuit area 40.

The read/write circuit area 10 may receive the decoded column address from the address decoder circuit area 30. The read/write circuit area 10 may select a bit line BL using the decoded column address. For example, the read/write circuit area 10 may receive data from the data input/output circuit area 20, and write the received data to the memory cell array area MCA.

The read/write circuit area 10 may read data from the memory cell array area MCA, and transfer the read data to the data input/output circuit area 20.

The read/write circuit area 10 may read data from a first storage area of the memory cell array area MCA, and write the read data to a second storage area of the memory cell array area MCA. For example, the read/write circuit area 10 may perform a copy-back operation.

The read/write circuit area 10 may include a page buffer (or page register) and a column selection circuit. Furthermore, the read/write circuit area 10 may include a detection amplifier, a write driver, and a row selection circuit.

The data input/output circuit area 20 may be connected to the read/write circuit area 10 through the data lines DL. The data input/output circuit area 20 may operate in response to the control of the control logic circuit area 40.

The data input/output circuit area 20 may exchange data DATA with the outside.

The data input/output circuit area 20 may transfer the data DATA received from the outside to the read/write circuit area 10 through the data lines DL.

The data input/output circuit area 20 may output the data DATA, which is received from the read/write circuit area 10 through the data lines DL, to the outside. For example, the data input/output circuit area 20 may include a component such as a data buffer.

The control logic circuit area 40 may be connected to the address decoder circuit area 30, the read/write circuit area 10, and the data input/output circuit area 20. The control logic circuit area 40 may control an operation of the semiconductor device 1. The control logic circuit area 40 may operate in response to a control signal CTRL received from the outside.

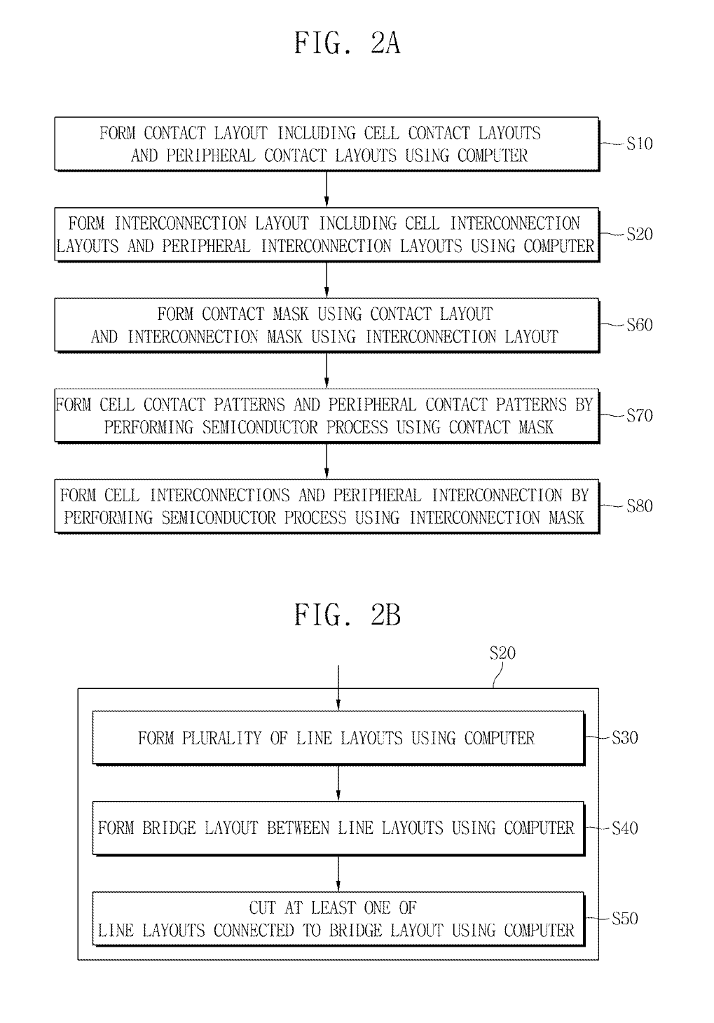

Next, a layout method of a semiconductor device in accordance with an embodiment of the inventive concept will be described with reference to FIGS. 2A and 2B.

Referring to FIGS. 1 and 2A, a contact layout including cell contact layouts and peripheral contact layouts may be created using a computer (S10). The cell contact layouts may be used for forming cell contact patterns in the memory cell array area MCA, and the peripheral contact layouts may be used for forming peripheral contact patterns in the peripheral circuit area PCA.

An interconnection layout including cell interconnection layouts and peripheral interconnection layouts may be created using the computer (S20). The cell interconnection layouts may be used for forming the bit lines BL in the memory cell array area MCA, and the peripheral interconnection layouts may be used for forming peripheral interconnections PW in the peripheral circuit area PCA.

The peripheral interconnection layouts may be used for forming the peripheral interconnections PW in the read/write circuit area 10 of the peripheral circuit area PCA. For example, the peripheral interconnection layouts may be used for forming the peripheral interconnections PW of the page buffer in the read/write circuit area 10, which may be electrically connected to the bit lines BL in the memory cell array area MCA.

A contact mask may be formed using the contact layout, and an interconnection mask may be formed using the interconnection layout (S60). The contact mask and the interconnection mask may be photo masks.

A semiconductor process using the contact mask may be performed to form cell contacts of the semiconductor device (S70). The semiconductor process using the contact mask may include a photolithography process in which a KrK laser, an ArF laser, a source of extreme ultraviolet (EUV) rays, or a source of X-rays is used as a light source.

A semiconductor process using the interconnection mask may be performed to form cell interconnections and peripheral interconnections of the semiconductor device (S80). The semiconductor process using the interconnection mask may include a photolithography process in which an off-axis polar illumination system is used. The semiconductor process using the interconnection mask may include a photolithography process in which a KrK laser, an ArF laser, a source of extreme ultraviolet (EUV) rays, or a source of X-rays is used as a light source.

The method of creating the interconnection layout including the cell interconnection layouts and the peripheral interconnection layouts using the computer will be described with reference to FIGS. 1, 2A, and 2B.

Referring to FIGS. 1, 2A, and 2B, a plurality of line layouts may be created using the computer (S30). The plurality of line layouts may include cell interconnection layouts in the memory cell array area MCA and peripheral line layouts in the peripheral circuit area PCA.

A bridge layout may be created using the computer (S40). The bridge layout may create a plurality of bridge layouts interposed between and connected to adjacent ones of the peripheral line layouts in the peripheral circuit area PCA.

At least one of the line layouts connected to the bridge layout may be cut using the computer (S50).

Next, examples of the above-described layout method will be described with reference to FIGS. 1 to 5B.

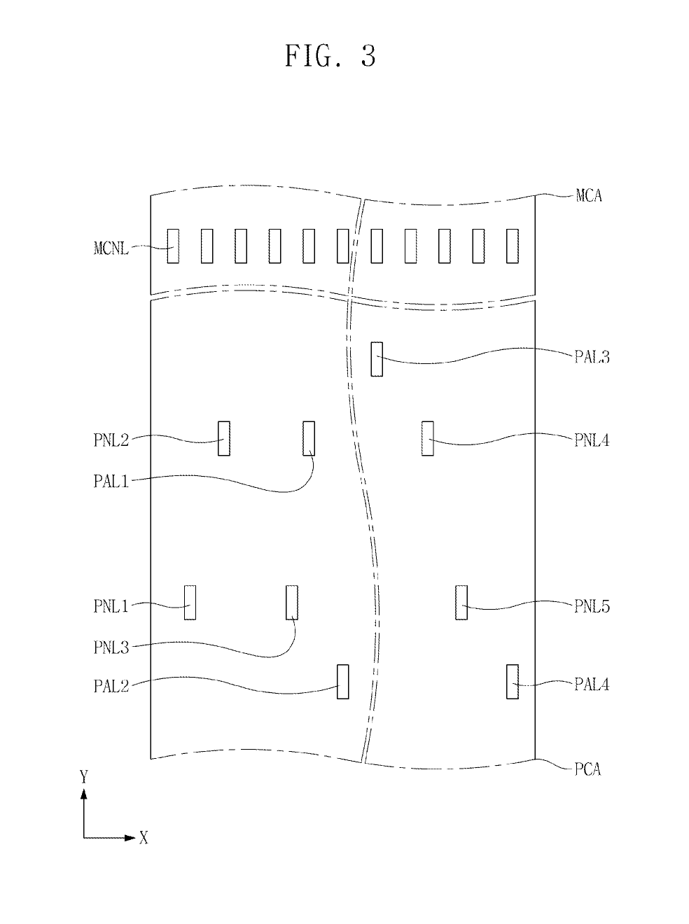

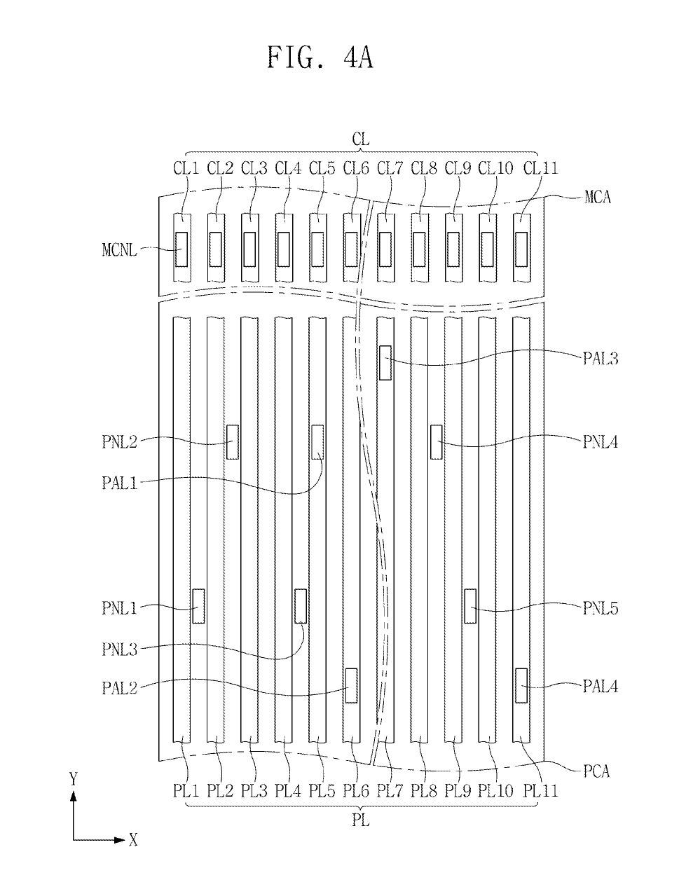

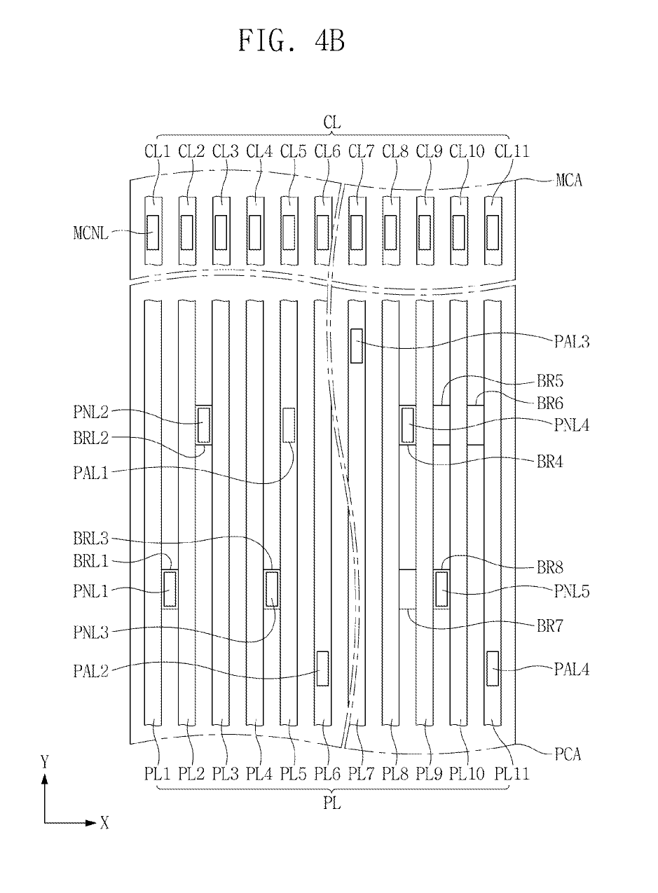

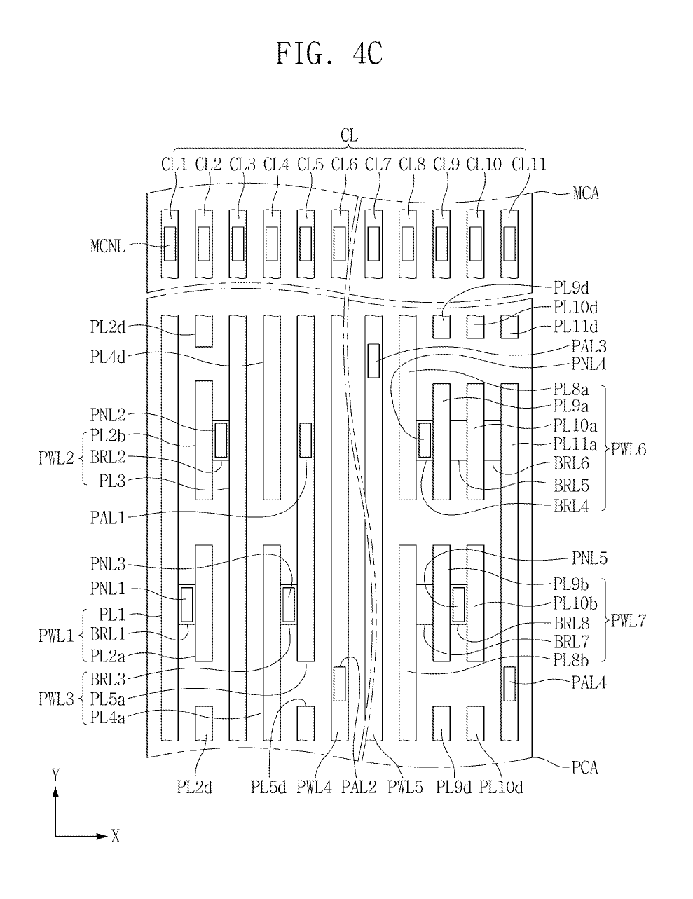

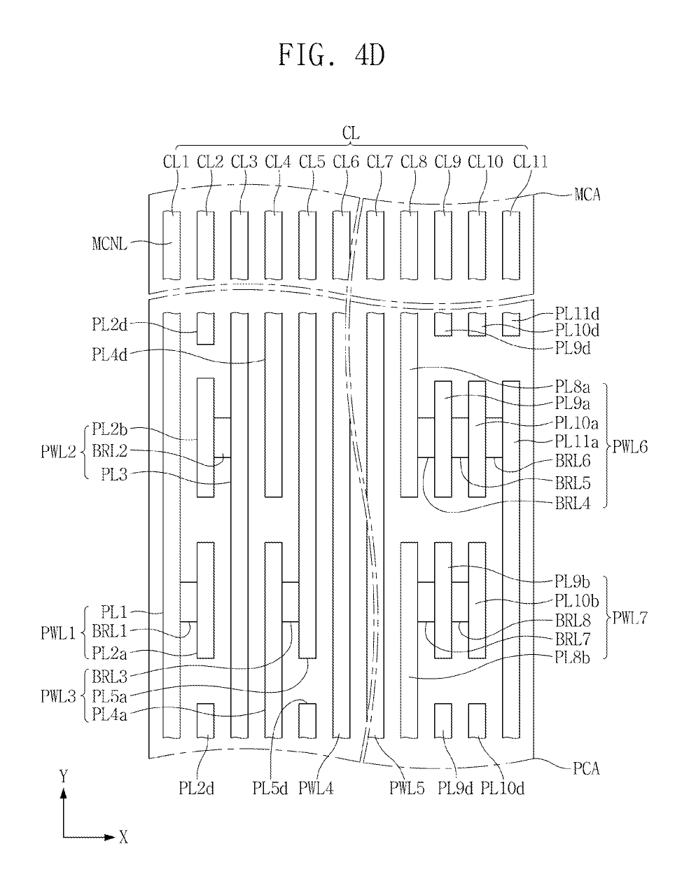

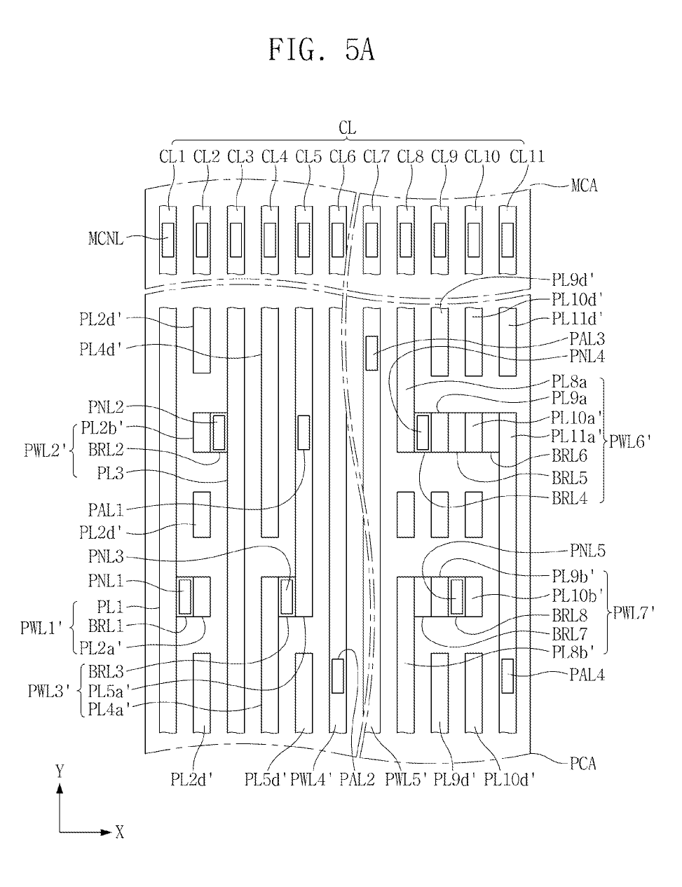

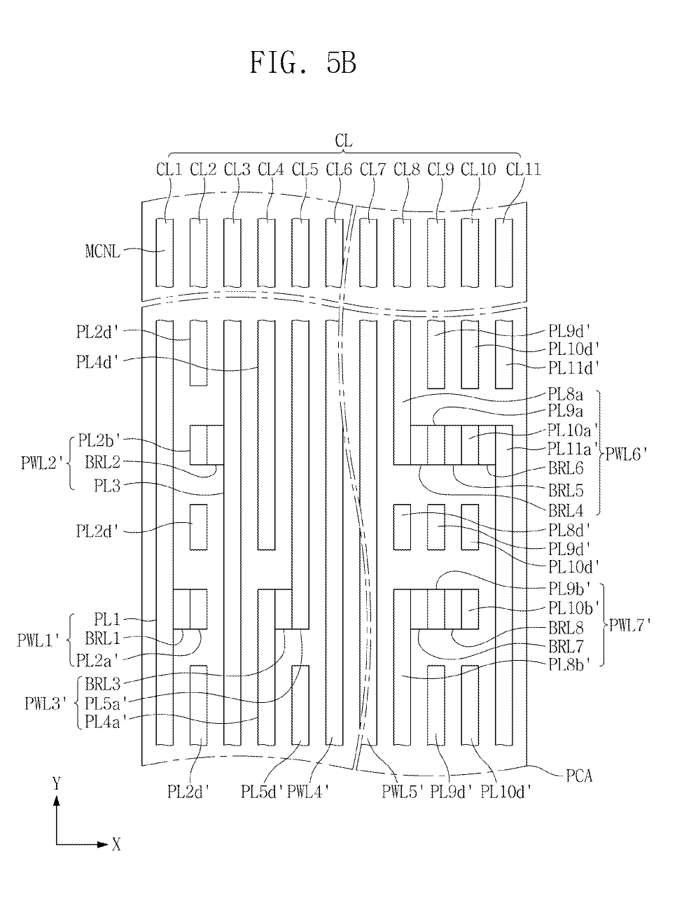

FIG. 3 is an example of the contact layout created in accordance with the inventive concept. FIGS. 4A to 4D illustrate an example of a method of creating the interconnection layout in accordance with the inventive concept. FIGS. 5A and 5B illustrate another example of a method of creating the interconnection layout in accordance with the inventive concept.

First, an example of creating the contact layout in accordance with the inventive concept will be described with reference to FIGS. 1, 2A, 2B, and 3.

The contact layout including cell contact layout MCNL and peripheral contact layout may be planned and created using a computer (S10), e.g.., in a computer-aided design process.

The cell contact layout MCNL may define cell contact patterns to be formed in the memory cell array area MCA. The peripheral contact layouts may define peripheral contact patterns to be formed in the peripheral circuit area PCA. The peripheral contact layout may include an aligned contact layout PAL1, PAL2, PAL3, and PAL4 and a misaligned contact layout PNL1, PNL2, PNL3, PNL4, and PNL5.

The cell contacts may be designed according to the cell contact layout MCNL to be arranged at uniform intervals in the MCA. The peripheral contacts designed according the peripheral contact layout may be arranged non-uniformly in the PCA. The cell contacts and the peripheral contacts may be designed to each be elongated in one direction. The cell contacts may be laid out at uniform intervals in a first direction (in an X direction), and each of the cell contacts and the peripheral contacts may be elongated in a second direction (in a Y direction) perpendicular to the first direction (in the X direction). For example, each of the cell contacts and the peripheral contacts may be designed to be rectangular.

Next, the design of the interconnection layout of the semiconductor device will be described with reference to FIGS. 1 to 4D.

Referring to FIGS. 1, 2A, 2B, 3, and 4A, a plurality of line layouts CL and PL may be designed using the computer (S30).

The plurality of line layouts CL and PL may include a cell line layout CL of cell lines to be formed in the memory cell array area MCA and a peripheral line layout PL formed of peripheral lines to be formed in the peripheral circuit area PCA. The lines designed according to the cell and peripheral line layouts CL and PL may have the same widths. The lines of the cell line layouts CL may be used for forming the bit lines BL (shown in FIG. 1) in the memory cell array area MCA.

The lines of the cell and peripheral line layouts CL and PL may be spaced apart from each other by equal distances in a given direction, e.g., the X direction in FIGS. 4A-D. The lines of the cell and peripheral line layouts CL and PL may thus extend longitudinally in the second direction (in the Y direction). The longitudinal direction Y of the plurality of lines of the cell and peripheral line layouts CL and PL may be the same as the longitudinal direction Y of the contacts of the cell contact layout MCNL and the peripheral contact layout PAL1, PAL2, PAL3, PAL4, PNL1, PNL2, PNL3, PNL4, and PNL5.

The cell line layout CL may include a first cell line CL1, a second cell line CL2, a third cell line CL3, a fourth cell line CL4, a fifth cell line CL5, a sixth cell line CL6, a seventh cell line CL7, an eighth cell line CL8, a ninth cell line CL9, a tenth cell line CL10, and an eleventh cell line CL11, which are serially arranged in the first direction (in the X direction).

The peripheral line layout PL may include a first peripheral line PL1, a second peripheral line PL2, a third peripheral line PL3, a fourth peripheral line PL4, a fifth peripheral line PL5, a sixth peripheral line PL6, a seventh peripheral line PL7, an eighth peripheral line PL8, a ninth peripheral line PL9, a tenth peripheral line PL10, and an eleventh peripheral line PL11, which are serially arranged in the first direction (in the X direction).

In the embodiment, the cell contacts of the cell contact layout MCNL may overlap and may be aligned with the cell lines of the cell line layout CL.

In the embodiment, the contacts of the aligned contact layout of the peripheral contact layout overlap and/or are aligned with the lines of the peripheral line layout PL, and the contacts of the misaligned contact layout of the peripheral contact layout do not overlap the lines of the peripheral line layout PL. In the figures illustrating this example of the present embodiment, the contacts of the aligned contact layout, i.e., the aligned contacts of the peripheral contact layout, include a first aligned contact PAL1, a second aligned contact PAL2, a third aligned contact PAL3, and a fourth aligned contact PAL4. The contacts of the misaligned contact layout, i.e., the misaligned contacts of the peripheral contact layout, include a first misaligned contact PNL1, a second misaligned contact PNL2, a third misaligned contact PNL3, a fourth misaligned contact PNL4, and a fifth misaligned contact PNL5.

The first aligned contact PAL1 may be aligned with and/or may overlap the fifth peripheral line PL5. The second aligned contact PAL2 may be aligned with and/or may overlap the sixth peripheral line PL6. The third aligned contact PAL3 may be aligned with and/or may overlap the seventh peripheral line PL7. The fourth aligned contact PAL4 may be aligned with and/or may overlap the eleventh peripheral line PL11.

The first misaligned contact PNL1 may be arranged between the first and second peripheral lines PL1 and PL2, the second misaligned contact layout PNL2 may be arranged between the second and third peripheral lines PL2 and PL3, the third misaligned contact PNL3 may be arranged between the fourth and fifth peripheral lines PL4 and PL5, the fourth misaligned contact PNL4 may be arranged between the eighth and ninth peripheral line PL8 and PL9, and the fifth misaligned contact PNL5 may be formed between the ninth and tenth peripheral lines PL9 and PL10.

Note, because the main contact layout MCNL and the peripheral contact layout define the contours and relative locations of the contacts, each contact of the main contact layout MCNL and each contact of the peripheral contact layout (contacts PAL1-PAL4 and PNL1-PNL5, for example) may be referred to hereinafter as a respective contact layout or contact layout section. Likewise, because the cell line layout CL and peripheral line layout PL define the contours and relative locations of the cell lines (CL1-CL11 and PL1-PL11, for example), each line may be referred to hereinafter as a respective line layout or line layout section.

Referring to FIGS. 1, 2A, 2B, 3, and 4B, a bridge layout may be designed using the computer (S40).

The bridge layout may be created for the peripheral circuit area PCA. The bridge layout may include bridges each arranged between adjacent ones of the line layouts. The bridge layout may include a first bridge BRL1, a second bridge BRL2, a third bridge BRL3, a fourth bridge BRL4, a fifth bridge BRL5, a sixth bridge BRL6, a seventh bridge BRL7, and an eighth bridge BRL8. Each of the bridges of the bridge layout may be elongated in the second direction (in the Y direction).

Note here also, because the bridge layout defines the shapes and relative locations of the bridges, each bridge may be referred to hereinafter as a respective bridge layout or bridge layout section.

The first bridge layout BRL1 may be disposed between the adjacent first and second peripheral line layouts PL1 and PL2, connected to the first and second peripheral line layouts PL1 and PL2, and may overlap the first misaligned contact layout PNL1. The length of the first bridge layout BRL1 (dimension in the Y direction) may be greater than the width of each of the first and second peripheral line layouts PL1 and PL2 and the distance between the first and second peripheral line layouts PL1 and PL2. The length (dimension in the Y direction) of the first bridge layout BRL1 may be approximately 3 to 15 times greater than the width of each of the first and second peripheral line layouts PL1 and PL2.

The second bridge layout BRL2 may be disposed between the adjacent second and third peripheral line layouts PL2 and PL3, connected to the second and third peripheral line layouts PL2 and PL3, and may overlap the second misaligned contact layout PNL2. The third bridge layout BRL3 may be disposed between the adjacent fourth and fifth peripheral line layouts PL4 and PL5, connected to the fourth and fifth peripheral line layouts PL4 and PL5, and may overlap the third misaligned contact layout PNL3. The fourth bridge layout BRL4 may be disposed between the adjacent eighth and ninth peripheral line layouts PL8 and PL9, connected to the eighth and ninth peripheral line layouts PL8 and PL9, and may overlap the fourth misaligned contact layout PNL4. The fifth bridge layout BRL5 may be disposed between the adjacent ninth and tenth peripheral line layouts PL9 and PL10, and may not overlap any of the peripheral contact layouts. The sixth bridge layout BRL6 may be disposed between the adjacent tenth and eleventh peripheral line layouts PL10 and PL11, and may not overlap any of the peripheral contact layouts. The seventh bridge layout BRL7 may be disposed between the adjacent eighth and ninth peripheral line layouts PL8 and PL9, and may not overlap any of the peripheral contact layouts. The eighth bridge layout BRL8 may be disposed between the adjacent ninth and tenth peripheral line layouts PL9 and PL10, connected to the ninth and tenth peripheral line layouts PL9 and PL10, and may overlap the fifth misaligned contact layout PNL5.

The fourth, fifth, and sixth bridge layouts BRL4, BRL5, and BRL6 may be serially arranged and aligned in the first direction (in the X direction). The seventh and eighth bridge layouts BRL7 and BRL8 may be serially arranged and aligned in the first direction (in the X direction).

Referring to FIGS. 1, 2A, 2B, 3, and 4C, some of the line layouts connected to the bridge layouts may be cut using the computer to produce an interconnection layout (S50), e.g., the interconnection layout may be generated in the computer-aided design process.

In the embodiment, for each bridge layout, at least one of two line layouts connected to the bridge layout is cut to produce an interconnection. For example, the second peripheral line layout PL2 (shown in FIG. 4B) of the first and second peripheral line layouts PL1 and PL2 (shown in FIG. 4B) connected to the first bridge layout BRL1 may be cut, leaving a severed part PL2a of the second peripheral line layout PL2 which is longer than and is connected to the first bridge layout BRL1. The first peripheral line layout PL1, the first bridge layout BRL1, and the severed part PL2a of the second peripheral line layout PL2 (shown in FIG. 4B) together constitute a first peripheral interconnection PWL1. Each interconnection may be referred to hereinafter as a respective interconnection layout or interconnection layout section.

Furthermore, the second peripheral line layout PL2 (shown in FIG. 4B) of the second and third peripheral line layouts PL2 and PL3 (shown in FIG. 4B) connected to the second bridge layout BRL2 may be cut, leaving a severed part PL2b of the second peripheral line layout PL2 which is longer than and connected to the second bridge layout BRL2. The third peripheral line layout PL3, the second bridge layout BRL2, and the severed part PL2b of the second peripheral line layout PL2 (shown in FIG. 4B) together constitute a second peripheral interconnection layout PWL2. Meanwhile, some severed parts the second peripheral line layout PL2 (shown in FIG. 4B) may constitute dummy layouts PL2d meaning that they are isolated from the other layouts and thus, represent a dummy pattern that will be electrically isolated in the device.

In the embodiment, both of the line layouts connected to any one of the bridge layouts may be cut to produce an interconnection layout. For example, the fourth and fifth peripheral line layouts PL4 and PL5 (shown in FIG. 4B) connected to the third bridge layout BRL3 may be cut, and severed parts PL4a and PL5a of the fourth and fifth peripheral line layouts PL4 and PL5 and the third bridge layout BRL3 connected thereto constitute a third respective interconnection layout PWL3.

In this case, the severed parts PL4a and PL5a connected to the third bridge layout BRL3 have parts facing each other with the third bridge layout BRL3 being interposed between the severed parts PL4a and PL5a. The severed parts PL4a and PL5a may each be longer than the third bridge layout BRL3.

Also, some severed parts of the fourth and fifth peripheral line layouts PL4 and PL5 (shown in FIG. 4B) may constitute dummy layouts PL4d and PL5d.

In the embodiment, a plurality of line layouts connected to the bridge layouts serially arranged and aligned in a direction (the X direction) perpendicular to the lengthwise direction of the line layouts (the Y direction) may be cut to produce peripheral interconnection layouts.

For example, the eighth, ninth, tenth, and eleventh peripheral line layouts PL8, PL9, PL10, and PL11 (shown in FIG. 4B) connected to the fourth, fifth, and sixth bridge layouts BRL4, BRL5, and BRL6 serially arranged in the first direction (in the X direction) may be cut to produce a sixth peripheral interconnection layout PWL6.

The eighth peripheral line layout PL8 (shown in FIG. 4B) and the eleventh peripheral line layout PL11 (shown in FIG. 4B) located to the sides of the ninth and tenth peripheral line layouts PL9, PL10 (shown in FIG. 4B) may be cut, and parts of the ninth and tenth peripheral line layouts PL9 and PL10 (shown in FIG. 4B) may, which are located to the sides of the fourth, fifth, and sixth bridge layouts BRL4, BRL5, and BRL6, be cut.

A severed part PL8a of the eighth peripheral line layout PL8 (shown in FIG. 4B), a severed part PL11a of the eleventh peripheral line layouts PL11 (shown in FIG. 4B), and severed parts PL9a and PL10a of the ninth and tenth peripheral line layouts PL9 and PL10 (shown in FIG. 4B) are connected to each other through the fourth, fifth, and sixth bridge layouts BRL4, BRL5, and BRL6 to constitute the sixth peripheral interconnection layout PWL6.

Furthermore, the eighth, ninth, and tenth peripheral line layouts PL8, PL9, and PL10 (shown in FIG. 4B) connected to the seventh and eighth bridge layouts BRL7 and BRL8 serially arranged in the first direction (in the X direction) may be cut, to form a seventh peripheral interconnection layout PWL7.

That is, a severed part PL8b of the eighth peripheral line layout PL8 (shown in FIG. 4B), severed parts PL9b and PL10b of the ninth and tenth peripheral line layouts PL9 and PL10 (shown in FIG. 4B), and the seventh and eighth bridge layouts BRL7 and BRL8 may be connected to each other to constitute the seventh peripheral interconnection layout PWL7.

Other severed parts of the ninth, tenth, and eleventh peripheral line layouts PL9, PL10, and PL11 (shown in FIG. 4B) may be dummy layouts PL9d, PL10d, and PL11d.

The sixth peripheral line layout PL6 (shown in FIG. 4B) may constitute a fourth peripheral interconnection layout PWL4, and the seventh peripheral line layout PL7 (shown in FIG. 4B) may constitute a fifth peripheral interconnection layout PWL5.

In this way, first to seventh peripheral interconnection layouts PWL1 to PWL7 may be formed as shown in FIG. 4D, by the computer-aided design process.

Next, another example of the forming of the interconnection layout (S20) in accordance with the inventive concept will be described with reference to FIGS. 5A and 5B.

Referring to FIGS. 1, 2A, 2B, 3, and 5A, the cell and peripheral line layouts CL and PL and the bridge layouts BRL1, BRL2, BRL3, BRL4, BRL5, BRL6, BRL7, and BRL8 may be designed as shown in and described above with reference to FIGS. 4A and 4B.

As was described above, in this respect, at least one of two line layouts connected to any one bridge layout may be cut and an interconnection layout may be formed. However, in this example, a severed part of the cut line layout has substantially the same shape as the bridge layout connecting the line layouts.

For example, the second peripheral line layout PL2 (shown in FIG. 4B) of the first and second peripheral line layouts PL1 and PL2 (shown in FIG. 4B) connected to the first bridge layout BRL1 may be cut, and a severed part PL2a′ of the second peripheral line layout PL2 which is connected to the first bridge layout BRL1 has substantially the same shape as the first bridge layout BRL1.

The first peripheral line layout PL1, the first bridge layout BRL1, and the severed part PL2a′ of the second peripheral line layout PL2 (shown in FIG. 4B) connected to each other constitute a first peripheral interconnection layout PWL1′.

Furthermore, the second peripheral line layout PL2 (shown in FIG. 4B) of the second and third peripheral line layouts PL2 and PL3 (shown in FIG. 4B) connected to the second bridge layout BRL2 may be cut, and the severed part PL2b′ of the second peripheral line layout PL2 connected to the second bridge layout BRL2 has substantially the same shape as the second bridge layout BRL2.

The third peripheral line layout PL3, the second bridge layout BRL2, and the severed part PL2b′ of the second peripheral line layout PL2 (shown in FIG. 4B) connected to each other constitute a second peripheral interconnection layout PWL2′.

Meanwhile, some of the severed parts of the second peripheral line layout PL2 (shown in FIG. 4B) may constitute dummy layouts PL2d′.

In this example as well, two line layouts connected to any one bridge layout may be cut and an interconnection layout may be formed. For example, the fourth and fifth peripheral line layouts PL4 and PL5 (shown in FIG. 4B) connected to the third bridge layout BRL3 may be cut and severed parts PL4a′ and PL5a′ connected to the third bridge layout BRL3 may be formed. The severed parts PL4a′ and PL5a′ terminate in the second direction (in the Y direction) at the ends of the third bridge layout BRL3, respectively. That is, ends of the severed parts PL4a′ and PL5a′ are aligned with the ends of the third bridge layout BRL3, respectively.

The third bridge layout BRL3 and the severed parts PL4a′ and PL5a′ of the fourth and fifth peripheral line layouts PL4 and PL5 (shown in FIG. 4B) connected to the third bridge layout BRL3 may constitute a third peripheral interconnection layout PWL3′.

Other severed parts of the fourth and fifth peripheral line layouts PL4 and PL5 (shown in FIG. 4B) may constitute dummy layouts PL4d′ and PL5d′.

Also, in this example, line layouts connected to bridge layouts serially arranged and aligned in a direction perpendicular to the line layouts may be cut to create a peripheral interconnection layout.

For example, the eighth, ninth, tenth, and eleventh peripheral line layouts PL8, PL9, PL10, and PL11 (shown in FIG. 4B) connected to the fourth, fifth, and sixth bridge layouts BRL4, BRL5, and BRL6 serially arranged in the first direction (in the X direction) may be cut, to create a sixth peripheral interconnection layout PWL6′. The eighth peripheral line layout PL8 (shown in FIG. 4B) and the eleventh peripheral line layout PL11 (shown in FIG. 4B) located at the sides of the eighth, ninth, tenth, and eleventh peripheral line layouts PL8, PL9, PL10, and PL11 (shown in FIG. 4B) may be cut, and parts of the ninth and tenth peripheral line layouts PL9 and PL10, which are located at the sides of the fourth, fifth, and sixth bridge layouts BRL4, BRL5, and BRL6, may be cut. A severed PL8a′ of the eighth peripheral line layout PL8 (shown in FIG. 4B), a severed part PL11a′ of the eleventh peripheral line layout PL11 (shown in FIG. 4B), and severed parts PL9a′ and PL10a′ of the ninth and tenth peripheral line layouts PL9 and PL10 (shown in FIG. 4B) connected to the fourth, fifth, and sixth bridge layouts BRL4, BRL5, and BRL6 may constitute the sixth peripheral interconnection layout PWL6′. Furthermore, the eighth, ninth, and tenth peripheral line layouts PL8, PL9, and PL10 (shown in FIG. 4B) connected to the seventh and eighth bridge layouts BRL7 and BRL8 serially arranged in the first direction (in the X direction) may be cut, to produce a seventh peripheral interconnection layout PWL7′.

In particular, a severed part PL8b′ of the eighth peripheral line layout PL8 (shown in FIG. 4B), severed parts PL9b′ and PL10b′ of the ninth and tenth peripheral line layouts PL9 and PL10 (shown in FIG. 4B), and the seventh and eighth bridge layouts BRL7 and BRL8 connected to each other may constitute the seventh peripheral interconnection layout PWL7′.

Other parts of the ninth, tenth, and eleventh peripheral line layouts PL9, PL10, and PL11 (shown in FIG. 4B) may constitute dummy layouts PL9d′, PL10d′, and PL11d′.

The sixth peripheral line layout PL6 (shown in FIG. 4B) may constitute a fourth peripheral interconnection layout PWL4′, and the seventh peripheral line layout PL7 (shown in FIG. 4B) may constitute a fifth peripheral interconnection layout PWL5′.

Therefore, as shown in FIG. 5B, first to seventh peripheral interconnection layouts PWL1′ to PWL7′ may be created through the design process.

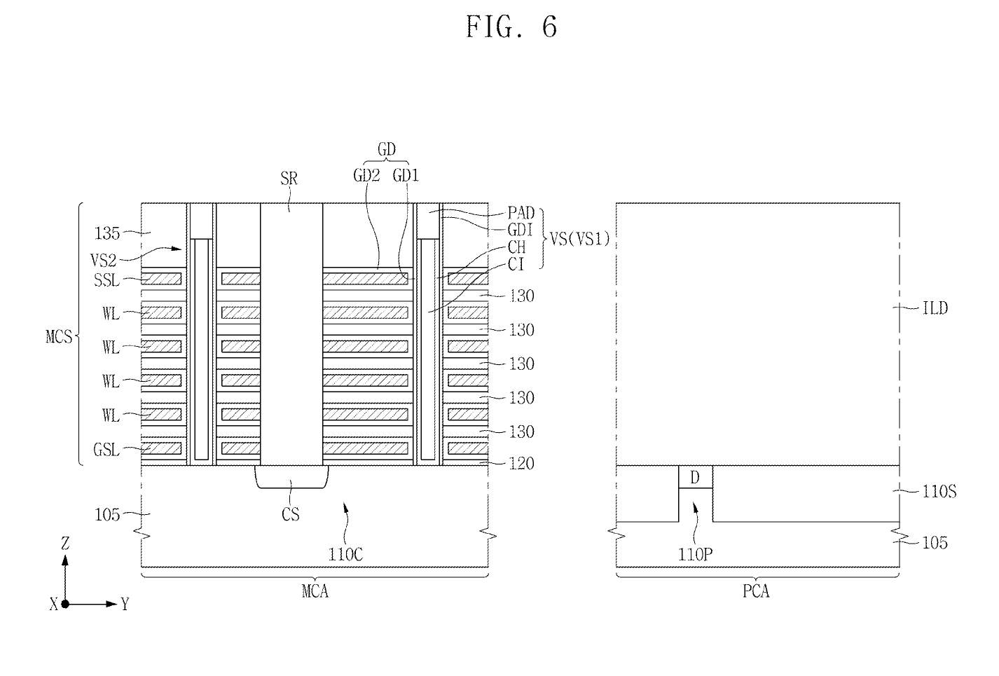

Next, a fabricating process based on the design process and examples of semiconductor devices fabricated in accordance with the inventive concept, will be described with reference to FIGS. 6-10.

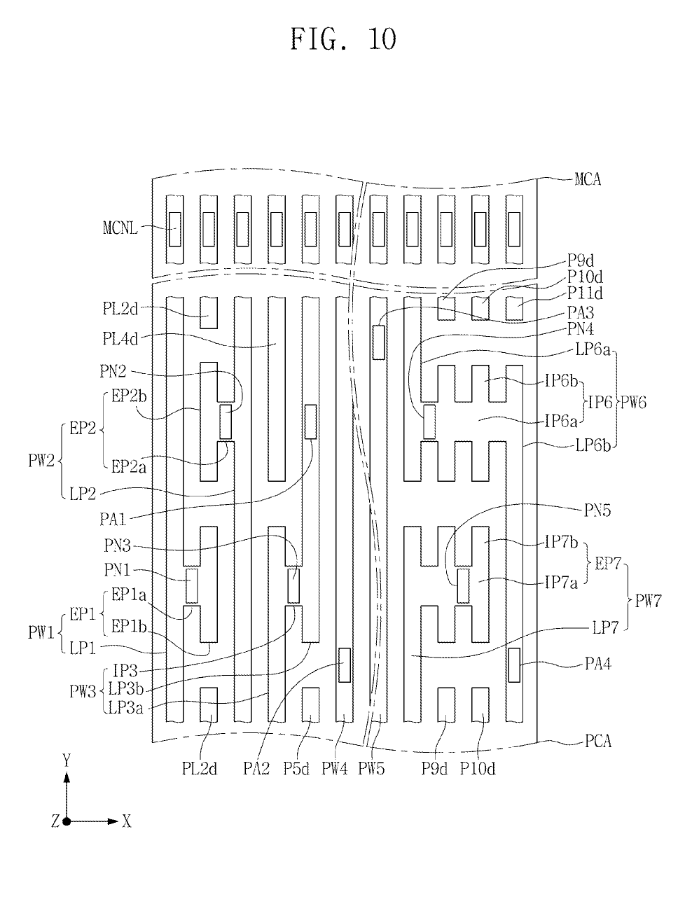

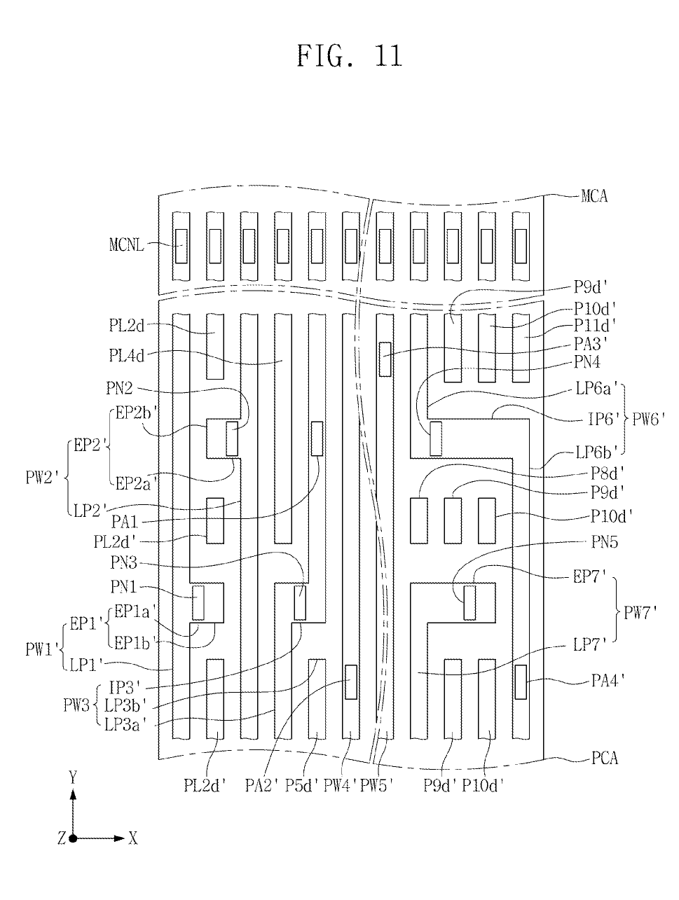

FIGS. 6 to 9 show a fabricating process of a semiconductor device. FIG. 10 is a plan view showing the fabricated semiconductor device including contact patterns and interconnections, which are formed using the contact layout shown in FIG. 3 and the interconnection layout shown in FIG. 4D. FIG. 11 is a plan view showing another semiconductor device including contact patterns and interconnections, which are formed using the contact layout shown in FIG. 3 and the interconnection layout shown in FIG. 5B.

Referring to FIGS. 1 and 6, a semiconductor substrate 105 having a memory cell array area MCA and a peripheral circuit area PCA may be provided. The substrate 105 may be a semiconductor substrate comprising silicon.

A peripheral circuit PC including a peripheral contact area D may be formed on the peripheral circuit area PCA of the semiconductor substrate 105, a memory cell structure MCS may be formed on a cell active area 110C in the memory cell array area MCA of the semiconductor substrate 105, and a peripheral insulating layer ILD may be formed on the peripheral circuit area PCA of the semiconductor substrate 105. The memory cell structure MCS may comprise a three-dimensional array of memory cells so as to include memory cells stacked in a direction (in a Z direction) perpendicular to the semiconductor substrate 105.

The peripheral circuit PC may have a circuit including a peripheral transistor. For example, the peripheral transistor may include a source S, a drain D (shown in FIG. 1), and a gate G In the embodiment, the peripheral contact area D may have the drain D (shown in FIG. 1) of the peripheral transistor of the peripheral circuit PC formed in a peripheral active area 110P defined by a trench isolation area 110S. However, the embodiment of the inventive concept is not limited thereto. For example, the peripheral contact area D may have the source S and/or the gate G instead.

The memory cell structure MCS may include vertical structures, gate electrodes WL, SSL, and GSL, gate dielectrics GD, a cell lower insulating layer 120, interlayer insulating layers between gates 130, a cell upper insulating layer 135, and the insulating isolation pattern SR.

The vertical structures may include first and second vertical structures VS1 and VS2 facing each other and between which the insulating isolation pattern SR is interposed.

The first and second vertical structures VS1 and VS2 each may include a core insulating pattern CI, a semiconductor pattern CH which covers side surfaces and a bottom of the core insulating pattern CI, a pad pattern PAD which covers an upper part of the core insulating pattern CI, and a first gate dielectric GD1 which covers an outside surface of the semiconductor pattern CH. The semiconductor pattern CH may be formed of silicon and used as a channel of the cell transistor CT (shown in FIG. 1). The pad pattern PAD may be formed of doped polysilicon. For example, the pad pattern PAD may be formed of N-type polysilicon.

The gate electrodes WL, SSL, and GSL may be formed to extend around the first and second vertical structures VS1 and VS2. The gate electrodes WL, SSL, and GSL may include an uppermost gate electrode SSL, a lowermost gate electrode GSL, and intermediate gate electrodes WL. The intermediate gate electrodes WL may be gate electrodes of the cell transistors CT and serve as word lines. Therefore, the intermediate gate electrodes WL may be referred to as word lines.

The insulating isolation pattern SR may be disposed between the first and second vertical structures VS1 and VS2 and may pass through the gate electrodes WL, SSL, and GSL.

A common source area CS may be formed in the semiconductor substrate 105 under the insulating isolation pattern SR. The common source area CS may have the same conductivity as the pad pattern PAD, for example, an N-type conductivity.

The interlayer insulating layers between gates 130 may be formed between the gate electrodes WL, SSL, and GSL.

The cell lower insulating layer 120 may be formed between the lowermost gate electrode GSL and the semiconductor substrate 105, and the cell upper insulating layer 135 may be formed on the uppermost gate electrode SSL.

The gate dielectrics GD may include both first gate dielectrics GD1 and second gate dielectrics GD2.

The second gate dielectric GD2 may be interposed between the gate electrodes GSL, WL, and SSL and the vertical structures VS1 and VS2, and may extend onto upper surfaces and bottoms of the gate electrodes GSL, WL, and SSL.

The gate dielectrics GD each may include a tunnel insulating layer, a data storage layer, and a blocking insulating layer. The data storage layer may be interposed between the tunnel insulating layer and the blocking insulating layer. For example, the first gate dielectric GD1 may include the tunnel insulating layer and the data storage layer, and the second gate dielectric GD2 may include the blocking insulating layer.

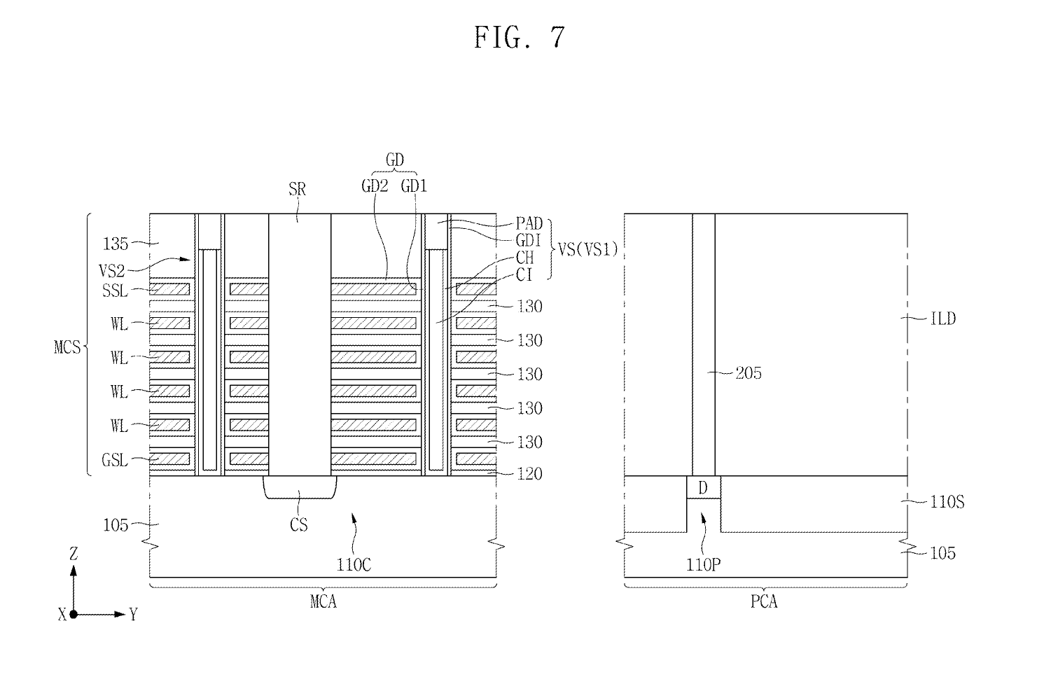

Referring to FIGS. 1 and 7, a peripheral contact plug 205, which passes through the peripheral insulating layer ILD of the peripheral circuit area PCA and is physically and electrically connected to the peripheral contact area D in the peripheral circuit area PCA of the semiconductor substrate 105, may be formed.

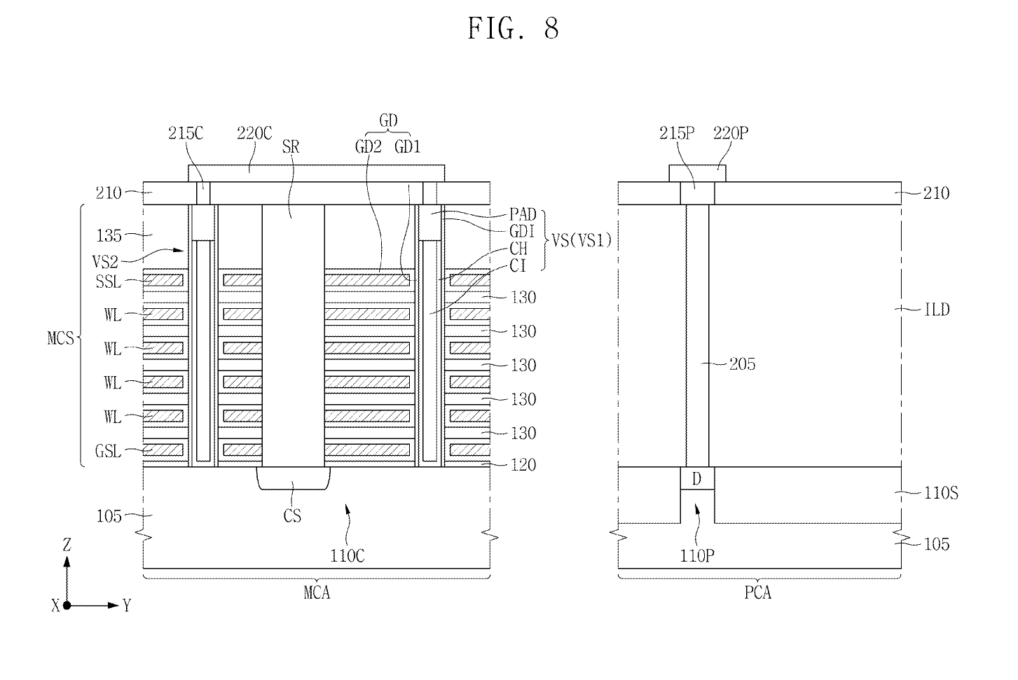

Referring to FIGS. 1 and 8, a lower interlayer insulating layer 210 may be formed on the semiconductor substrate 105 having the peripheral contact plug 205. The lower interlayer insulating layer 210 may cover the memory cell structure MCS and the peripheral insulating layer ILD. Cell lower contact patterns 215C and a peripheral lower contact pattern 215P passing through the lower interlayer insulating layer 210 may be formed.

The cell lower contact patterns 215C may pass through the lower interlayer insulating layer 210 disposed on the memory cell array area MCA of the semiconductor substrate 105, and may be physically and/or electrically connected to the pad patterns PAD of the vertical structures VS1 and VS2.

The peripheral lower contact pattern 215P may pass through the lower interlayer insulating layer 210 disposed on the peripheral circuit area PCA of the semiconductor substrate 105, and may be physically and/or electrically connected to the peripheral contact plug 205.

A cell auxiliary pattern 220C, which overlaps the cell lower contact patterns 215C and electrically connects the cell lower contact patterns 215C, may be formed, and a peripheral auxiliary pattern 220P, which overlaps the peripheral lower contact pattern 215P and is electrically connected to the peripheral lower contact pattern 215P, may be formed.

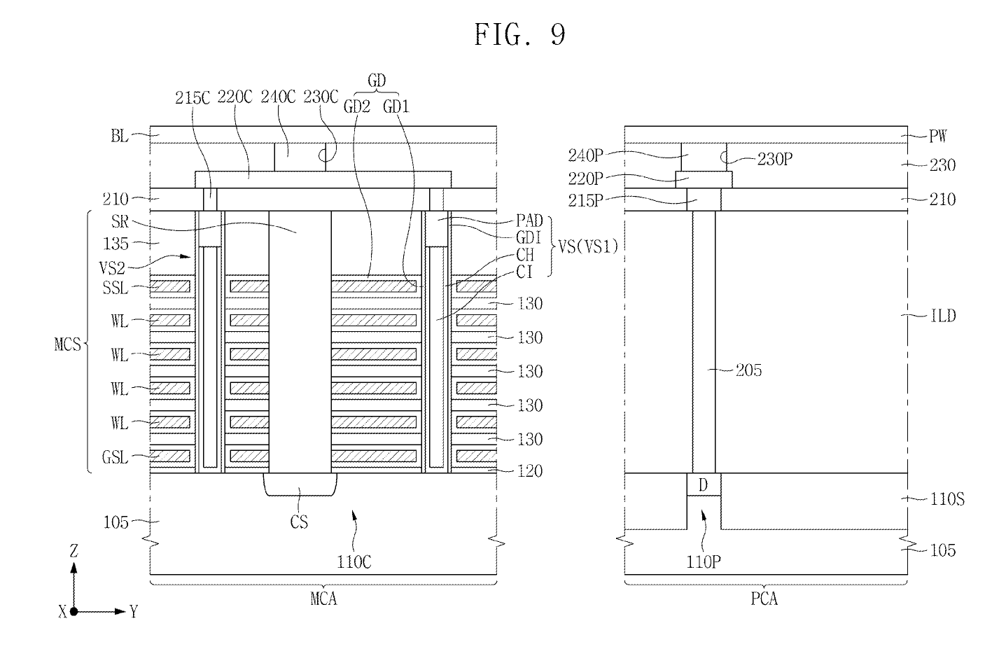

Referring to FIGS. 1 and 9, an upper interlayer insulating layer 230 may be formed on the semiconductor substrate 105 having the cell auxiliary pattern 220C and the peripheral auxiliary pattern 220P.

A cell contact pattern 240C and a peripheral contact pattern 240P, which pass through the upper interlayer insulating layer 230, may be formed, and a bit line BL and a peripheral interconnection PW may be formed on the upper interlayer insulating layer 230.

The bit line BL may overlap the cell contact pattern 240C and may be electrically connected to the cell contact pattern 240C.

The peripheral interconnection PW may overlap the peripheral contact pattern 240P and may be electrically connected to the peripheral contact pattern 240P.

The cell contact pattern 240C and the peripheral contact pattern 240P may be formed by forming a contact mask (S60 in FIG. 2A) on the upper interlayer insulating layer 230, forming a cell contact hole 230C and a peripheral contact hole 230P, which pass through the upper interlayer insulating layer 230 using the contact mask, and filling the cell and peripheral contact holes 230C and 230P with conductive material. The contact mask may be formed to correspond to the contact layout shown in and described above with reference to FIG. 3.

More specifically, the contact mask may be formed by forming a photoresist pattern using a photolithography process, wherein the photoresist pattern is a photoresist layer having openings therethrough corresponding to the contact layouts shown in FIG. 3, and an etching process in which the upper interlayer insulating layer 230 is etched using the photoresist pattern as an etch mask.

Subsequently, the etch mask is removed.

The bit line BL and the peripheral interconnection PW may be formed by forming a conductive layer (through a deposition process) on the upper interlayer insulating layer 230, and patterning the conductive layer using the interconnection mask formed (S60 in FIG. 2A) on the conductive layer.

The interconnection mask may be formed to correspond to the interconnection layout shown in and described with reference to FIG. 4D or the interconnection layout shown in and described with reference to FIG. 5B. In any case, the interconnection mask may be formed by a photolithography process in which a photoresist pattern is formed on the conductive layer and an etching process in which the conductive layer is etched using the photoresist pattern as an etch mask. The photoresist pattern is a layer of photoresist having openings therethrough corresponding to the interconnection layouts (FIG. 4D or 5B).

The photolithography process may be carried out using an off-axis illumination system. The off-axis illumination system may have a KrK laser, an ArF laser, a source of extreme ultraviolet (EUV) rays, or a source of X-rays as its light source.

First, a semiconductor device formed using the interconnection layout shown in and described with reference to FIG. 4D will be described with reference to FIG. 10.

Referring to FIGS. 9 and 10, the peripheral contact pattern 240P in FIG. 9 may correspond to any one of peripheral contact patterns PA1, PA2, PA3, PA4, PN1, PN2, PN3, PN4, and PN5 in FIG. 10. The cell contact pattern 240C may correspond to any of the cell contact layouts of MCNL shown in and described with reference to FIG. 3, and the peripheral contact patterns PA1, PA2, PA3, PA4, PN1, PN2, PN3, PN4, and PN5 may correspond to the peripheral contact layouts PAL1, PAL2, PAL3, PAL4, PNL1, PNL2, PNL3, PNL4, and PNL5 shown in and described with reference to FIG. 3.

Thus, a plurality of the peripheral interconnection PW may be formed to include a first peripheral interconnection PW1, a second peripheral interconnection PW2, a third peripheral interconnection PW3, a fourth peripheral interconnection PW4, a fifth peripheral interconnection PW5, a sixth peripheral interconnection PW6, and a seventh peripheral interconnection PW7 corresponding to those shown in and described with reference to FIG. 4C.

The first peripheral interconnection PW1 may include a line part LP1 and an extension part EP1 which extends from the line part LP1. The extension part EP1 of the first peripheral interconnection PW1 may include a first extension part EP1a and a second extension part EP1b. The first extension part EP1a of the first peripheral interconnection PW1 may be formed between the line part LP1 and the second extension part EP1b. The first extension part EP1a of the first peripheral interconnection PW1 may correspond to the first bridge layout BRL1 shown in and described with reference to FIG. 4B.

The second extension part EP1b of the first peripheral interconnection PW1 may be longer than the first extension part EP1a in the second direction (in the Y direction).

The second peripheral interconnection PW2 may include a line part LP2 and an extension part EP2 which extends from the line part LP2. The extension part EP2 of the second peripheral interconnection PW2 may include a first extension part EP2a and a second extension part EP2b. The first extension part EP2a of the second peripheral interconnection PW2 may be formed between the line part LP2 and the second extension part EP2b. The first extension part EP2a of the second peripheral interconnection PW2 may correspond to the second bridge layout BRL2 shown in and described with reference to FIG. 4B. The second extension part EP2b of the second peripheral interconnection PW2 may be longer than the first extension part EP2a in the second direction (in the Y direction).

The third peripheral interconnection PW3 may include a first line part LP3a, a second line part LP3b, and an extension part IP3 disposed between the first and second line parts LP3a and LP3b.

The extension part IP3 of the third peripheral interconnection PW3 may correspond to the third bridge layout BRL3 shown in and described with reference to FIG. 4B.

The extension part IP3 of the third peripheral interconnection PW3 may be interposed between parts of the first and second line parts LP3a and LP3b which face each other.

The length of the parts of the first and second line parts LP3a and LP3b which face each other may be greater than the length of the extension part IP3 of the third peripheral interconnection PW3, in the second direction (in the Y direction).

The fourth and fifth peripheral interconnections PW4 and PW5 may consist of linear and parallel segments of conductive material.

The sixth peripheral interconnection PW6 may include a first line part LP6a, a second line part LP6b, and an extension part IP6 disposed between the first and second line parts LP6a and LP6b.

The extension part IP6 of the sixth peripheral interconnection PW6 may correspond to the fourth, fifth, and sixth bridge layouts BRL4, BRL5, and BRL6 and the severed parts PL9a and PL9b of the ninth and tenth peripheral line layouts PL9 and PL10 connected to the fourth, fifth, and sixth bridge layouts BRL4, BRL5, and BRL6 (all shown in FIG. 4B).

The extension part IP6 of the sixth peripheral interconnection PW6 may include a first extension part IP6a interposed between parts of the first and second line parts LP6a and LP6b which face each other, and protruding parts IP6b which protrude from the first extension part IP6a in a longitudinal direction of the first and second line parts LP6a and LP6b.

The seventh peripheral interconnection PW7 may include a line part LP7 and an extension part EP7 which extends from the line part LP7. The extension part EP7 of the seventh peripheral interconnection PW7 may include a part IP7a which extends from the line part LP7 in the first direction (in the X direction), and parts IP7b which extend from the extended part IP7a in the second direction (in the Y direction).

The extension parts EP1 and EP2 of the first and second peripheral interconnections PW1 and PW2 may be formed between the line parts LP1 and LP2 of the first and second peripheral interconnection PW1 and PW2. Furthermore, dummy patterns PL2d (patterns which are electrically isolated in the device) may be disposed between the line parts LP1 and LP2 of the first and second peripheral interconnection PW1 and PW2. Furthermore, a dummy pattern PL4d may be disposed between the second and third peripheral interconnection PW2 and PW3, and a dummy pattern P5d may be disposed between the third and fourth peripheral interconnection PW3 and PW4. Furthermore, dummy patterns P9d, P10d, and P11d may be disposed on parts adjacent to the sixth peripheral interconnection PW6 and parts adjacent to seventh peripheral interconnection PW7.

Next, a semiconductor device formed using the interconnection layout shown in and described with reference to FIG. 5B will be described with reference to FIG. 11.

Referring to FIGS. 9 and 11, the peripheral contact pattern 240P may correspond to any one of peripheral contact patterns PA1′, PA2′, PA3′, PA4′, PN1′, PN2′, PN3′, PN4′, and PN5′ shown in FIG. 11. A plurality of the cell contact patterns 240C may correspond to the cell contact layouts of MCNL shown in and described with reference to FIG. 3, and the peripheral contact patterns PA1′, PA2′, PA3′, PA4′, PN1′, PN2′, PN3′, PN4′, and PN5′ may correspond to the peripheral contact layouts PAL1, PAL2, PAL3, PAL4, PNL1, PNL2, PNL3, PNL4, and PNL5 shown in and described with reference to FIG. 3.

A plurality of the peripheral interconnections PW may be formed to include a first peripheral interconnection PW1′, a second peripheral interconnection PW2′, a third peripheral interconnection PW3′, a fourth peripheral interconnection PW4′, a fifth peripheral interconnection PW5′, a sixth peripheral interconnection PW6′, and a seventh peripheral interconnection PW7′.

The first to seventh peripheral interconnections PW1′, PW2′, PW3′, PW4′, PW5′, PW6′, and PW7′ may correspond to the first to seventh peripheral interconnection layouts PWL1′, PWL2′, PWL3′, PWL4′, PWL5′, PWL6′, and PWL7′ shown in and described with reference to FIG. 5A.

The first peripheral interconnection PW1′ may include a line part LP1′ and an extension part EP1′ which extends from the line part LP1′. A first misaligned peripheral contact pattern PN1′ may overlap the extension part EP1′ of the first peripheral interconnection PW1′.

The second peripheral interconnection PW2′ may include a line part LP2′ and an extension part EP2′ which extends from the line part LP1′. A second misaligned peripheral contact pattern PN2′ may overlap the extension part EP2′ of the second peripheral interconnection PW2′.

The third peripheral interconnection PW3′ may include a first line part LP3a′, a second line part LP3b′, and an extension part IP3′ disposed between the first and second line parts LP3a′ and LP3b′. The extension part IP3′ of the third peripheral interconnection PW3′ may be interposed between facing parts of the first and second line parts LP3a′ and LP3b′.

The sixth peripheral interconnection PW6′ may include a first line part LP6a′, a second line part LP6b′, and an extension part IP6′ disposed between the first and second line parts LP6a′ and LP6b′.

The seventh peripheral interconnection PW7′ may include a line part LP7′ and an extension part EP7′ which extends from the line part LP7′.

The extension parts EP1′ and EP2′ of the first and second peripheral interconnection PW1′ and PW2′ may be formed between the line parts LP1′ and LP2′ of the first and second peripheral interconnection PW1′ and PW2′. Furthermore, dummy patterns PL2d′ may be disposed between the line parts LP1′ and LP2′ of the first and second peripheral interconnection PW1′ and PW2′. Furthermore, a dummy pattern PL4d may be disposed between the second and third peripheral interconnection PW2′ and PW3′, and a dummy pattern P5d′ may be disposed between the third and fourth peripheral interconnection PW3′ and PW4′. Furthermore, some dummy patterns P9d′, P10d′, and P11d′ may be disposed adjacent to the sixth peripheral interconnection PW6′ whereas others may be disposed adjacent to seventh peripheral interconnection PW7′.

According to the inventive concept, a semiconductor device may be designed and fabricated so that the pattern density of the bit lines BL in the memory cell array area MCA is similar to the pattern density of the peripheral interconnections PW in the peripheral circuit area PCA. Therefore, the design process allows for an increased margin in the fabrication process including a photolithography process and an etching process.

Also, according to the inventive concept, an interconnection layout method is provided in which peripheral interconnections PW may be formed without the need to move locations where the peripheral contacts are best to be formed in the peripheral circuit area PCA.

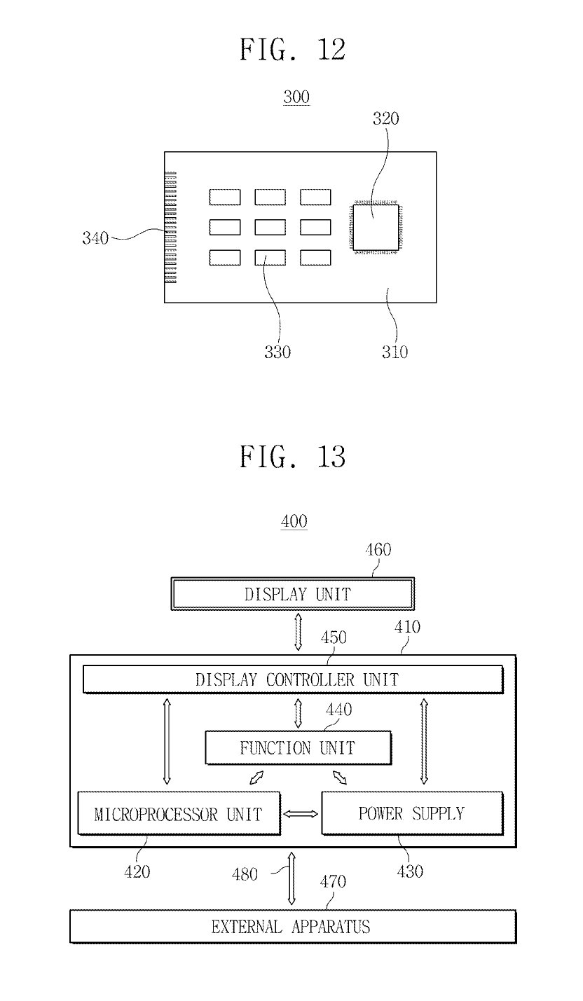

FIG. 12 illustrates a semiconductor module 300 fabricated in accordance with the inventive concept.

Referring to FIG. 12, the semiconductor module 300 may include memory devices 330 formed on a module substrate 310. The semiconductor module 300 may include a semiconductor device 320 installed on the module substrate 310. The semiconductor device 320 and the memory devices 330 may be made using an embodiment according to the inventive concept. Input/output terminals 340 may be disposed on at least one side of the module substrate 310.

FIG. 13 illustrates an electronic system 400 in accordance with the inventive concept.

Referring to FIG. 13, the electronic system 400 may include a body 410. The body 410 may support a microprocessor unit 420, a power supply 430, a function unit 440, and/or a display controller unit 450. The body 410 may be a system board or a motherboard comprising a printed circuit board (PCB).

The microprocessor unit 420 may be made using an embodiment according to the inventive concept.

The microprocessor unit 420, the power supply 430, the function unit 440, and the display controller unit 450 may be installed in or mounted on the body 410. A display unit 460 may be disposed on an upper surface of the body 410 or outside the body 410. For example, the display unit 460 may be disposed on a surface of the body 410, and display an image processed by the display controller unit 450. The power supply 430 may receive a constant voltage from an external power supply, divide the voltage into various voltage levels, and supply the voltages to the microprocessor unit 420, the function unit 440, and the display controller unit 450. The microprocessor unit 420 may receive a voltage from the power supply 430 and control the function unit 440 and the display unit 460.

The function unit 440 may perform various functions of the electronic system 400. For example, when the electronic system 400 is a mobile electronic product such as a cellular phone, the function unit 440 may include various components to perform dialing, or wireless communication functions such as video output to the display unit 460 or voice output to a speaker through communication with an external apparatus 470, and when a camera is included, it may serve as an image processor.

In the embodiment, when the electronic system 400 is connected to a memory card, and the like to expand the capacity, the function unit 440 may be a memory card controller. The function unit 440 may exchange signals with the external apparatus 470 through a wired or wireless communication unit 480.

Furthermore, when the electronic system 400 requires a Universal Serial Bus (USB) to expand the functions, the function unit 440 may serve as an interface controller.

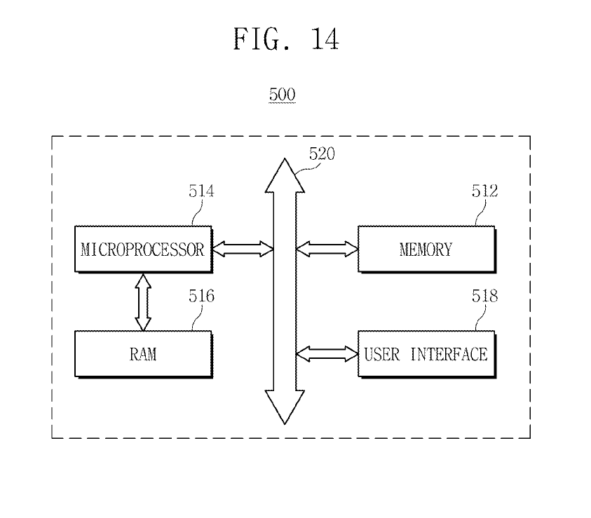

FIG. 14 illustrates another electronic system 500 in accordance with the inventive concept.

Referring to FIG. 14, an electronic system 500 may include a semiconductor device made by an embodiment according to the inventive concept. The electronic system 500 may be applied to a mobile device or a computer. For example, the electronic system 500 may include a memory system 512, a microprocessor 514, a RAM 516, and a user interface 518 which perform data communication using a bus 520. The microprocessor 514 may program and control the electronic system 500. The RAM 516 may be used as an operational memory of the microprocessor 514. The microprocessor 514, the RAM 516, and/or other components may be assembled within a single package. The memory system 512 may be made using an embodiment according to the inventive concept.

The user interface 518 may be used to input data to the electronic system 500, or output data from the electronic system 500. The memory system 512 may store operational codes of the microprocessor 514, data processed by the microprocessor 514, or data received from the outside. The memory system 512 may include a controller and a memory.

As described above, an interconnection layout method according to the inventive concept allows for a high degree of freedom in arranging contacts of a semiconductor device. The inventive concept also allows for a wider process margin in the manufacturing of semiconductor devices.

Finally, embodiments of the inventive concept and examples thereof have been described above in detail. The inventive concept may, however, be embodied in many different forms and should not be construed as being limited to the embodiments described above. Rather, these embodiments were described so that this disclosure is thorough and complete, and fully conveys the inventive concept to those skilled in the art. Thus, the true spirit and scope of the inventive concept is not limited by the embodiment and examples described above but by the following claims.

What is claimed is:

1. A layout method of a semiconductor device, comprising:
creating a contact layout including cell contact layouts and peripheral contact layouts using a computer, each of contact layouts having a form corresponding to that of a contact of the semiconductor device; and
creating an interconnection layout including a layout of cell interconnections and peripheral interconnections using the computer,
wherein the creating of the interconnection layout comprises:
creating a plurality of line layouts that are spaced apart from each other by uniform distances in a first direction, and have the same widths, and each of which has a linear form extending longitudinally in a second direction perpendicular to the first direction, wherein the plurality of line layouts include cell interconnection layouts and peripheral line layouts, the peripheral line layouts include a first peripheral line layout and a second peripheral line layout adjacent to each other, and the peripheral contact layouts include a misaligned contact layout disposed between the first and second peripheral line layouts;
creating a bridge layout extending to and from the first and second peripheral line layouts in the first direction and overlapping the misaligned contact layout; and
cutting the second peripheral line layout into discrete parts separated from each other in the second direction.

2. The layout method according to claim 1, wherein the bridge layout is elongated in the second direction.

3. The layout method according to claim 1, wherein the misaligned contact layout is elongated in the second direction.

4. The layout method according to claim 1, wherein the discrete parts of the second peripheral line layout include a severed part connected to the bridge layout and a dummy layout which is isolated from the others of the layouts of the interconnection layout.

5. The layout method according to claim 4, wherein the severed part of the second peripheral line layout is longer than the bridge layout in the second direction.

6. The layout method according to claim 1, wherein the length, in the second direction, of the bridge layout is 3 to 15 times greater than the width of each of the line layouts.

7. A method of manufacturing a semiconductor device, comprising:
forming a contact mask and an interconnection mask using the layout method of claim 1, wherein the contact mask is formed using the contact layout, and the interconnection mask is formed using the interconnection layout;
forming an interlayer insulating layer on a substrate having a memory cell array area and a peripheral circuit area;
forming cell contact patterns and peripheral contact patterns passing through the interlayer insulating layer using the contact mask; and
forming cell interconnections and peripheral interconnections on the interlayer insulating layer using the interconnection mask.

8. The method according to claim 7, wherein any one of the peripheral interconnections includes a line part and an extension part extending in a first direction, in a frame of reference in which the manufacturing of the device is taking place, from the line part.

9. The method according to claim 8, wherein the extension part includes a first extension and a second extension, and the first extension is interposed between the second extension and the line part.

10. The method according to claim 9, wherein the second extension is longer than the first extension in a second direction perpendicular to the first direction in said frame of reference.

11. The method according to claim 8, wherein the length of the extension part in a second direction, perpendicular to the first direction in said frame of reference, is greater than the width of the line part.

12. The method according to claim 9, wherein the extension part is elongated in a second direction perpendicular to the first direction in said frame of reference.

13. The method according to claim 7, wherein any one of the peripheral interconnections includes a first line part and an extension part extending in a first direction, in a frame of reference in which the manufacturing of the device is taking place, from the first line part, and a second line part connected to the extension part.

14. The method according to claim 13, wherein the extension part is interposed between parts of the first and second line parts that face each other, and
the length of each of said parts of the first and second line parts which face each other is greater than the length of the extension part in a second direction perpendicular to the first direction in said frame of reference.

15. The method according to claim 7, wherein the forming of the cell interconnections and the peripheral interconnections on the interlayer insulating layer using the interconnection mask is performed using a photolithography process in which a KrK laser, an ArF laser, a source of extreme ultraviolet (EUV) rays, or a source of X-rays is used as a light source.

16. A method of manufacturing a semiconductor device, comprising:
a computer-aided design process of creating a layout of mask openings corresponding to contacts of the device and interconnections of the device; and
a fabrication operation including a semiconductor process, based on the design process, of forming the contacts and interconnections on a substrate both in a memory cell area of the device and a peripheral circuit area of the device outside the memory cell area;
wherein the computer-aided design process comprises:
creating a contact layout including contact layout sections defining the contours and relative locations of cell contacts to be formed by the fabrication operation in the memory cell area, and peripheral contact layout sections defining the contours and relative locations of peripheral contacts to be formed in the peripheral circuit area by the fabrication operation, and
creating an interconnection layout defining the contours and relative locations of cell interconnections to be formed by the fabrication operation in the memory cell area and peripheral interconnections to be formed by the fabrication operation in the peripheral circuit area,
wherein the interconnection layout includes line-shaped layout sections of equal widths spaced apart from each other by uniform distances in a first direction and each of which extends longitudinally in a second direction perpendicular to the first direction, the line-shaped layout sections including a first peripheral line-shaped layout section and a second peripheral line-shaped layout section adjacent to each other, and the peripheral contact layout sections including a misaligned contact layout section interposed between the first and second peripheral line layout sections with the contact layout and the interconnection layout being superimposed, and
a bridge layout section interconnecting the first and second peripheral line layout sections in the first direction, and overlapping the misaligned contact layout section with the contact layout and the interconnection layout being superimposed, and
wherein the second peripheral line layout section is discontinuous in the second direction so as to have discrete parts separated from each other in the second direction, only one of the discrete parts being connected to the bridge layout section; and
wherein the semiconductor process comprises:
forming an interlayer insulating layer on the substrate as extending over both the memory cell array area and peripheral circuit area,
forming contacts that pass through the interlayer insulating layer, and
forming conductive interconnection patterns on the interlayer insulating layer as electrically conductively connected to the contacts.

17. The method according to claim 16, wherein the semiconductor process comprises:
forming a contact mask on the interlayer insulating layer, the contact mask having openings that expose the interlayer insulating layer, the openings corresponding to the cell contacts and peripheral contacts defined by the contact layout,
etching the interlayer insulating layer using the contact mask as an etch mask to form contact openings in the interlayer insulating layer,
filling the contact openings with conductive material to form the contacts,
subsequently forming a conductive layer on the interlayer insulating layer,
forming an interconnection mask on the conductive layer, the interconnection mask having openings that expose the conductive layer, the openings of the interconnection mask corresponding to the cell interconnections and peripheral interconnections defined by the interconnection layout, and
etching the conductive layer using the interconnection mask as an etch mask to form the conductive interconnection patterns.

18. The method according to claim 16, wherein the contact layout and the interconnection line layout when superimposed define the contours and relative locations of a plurality of cell contacts overlapped by respective ones of the line-shaped layout sections.

19. The method according to claim 16, wherein the discrete parts of the second peripheral line layout section include a severed part connected to the bridge layout section and a dummy layout section which is isolated from all of the other layout sections of the interconnection layout, and
the forming of the conductive interconnection patterns comprises forming a dummy pattern that is electrically isolated in the device.

20. The method according to claim 19, wherein the severed part of the second peripheral line layout section is longer than the bridge layout in the second direction.
